(19) United States
(12) Patent Application Publication
(10) Pub. No.: US 2026/0058558 A1
(43) Pub. Date: Feb. 26, 2026

(54) CLOCK SIGNAL GENERATION CIRCUIT, POWER SUPPLY CONTROL DEVICE, AND SWITCHING POWER SUPPLY DEVICE

(71) Applicant: ROHM Co., Ltd., Kyoto (JP)

(72) Inventors: Shidong Guan, Kyoto (JP); Francois Margallo, Kyoto (JP)

(73) Assignee: ROHM Co., Ltd., Kyoto (JP)

(21) Appl. No.: 19/300,666

(22) Filed: Aug. 14, 2025

(30) Foreign Application Priority Data
Aug. 22, 2024 (JP) 2024-140816

(51) Int. Cl. H02M 3/158; H02M 1/44; H03K 4/06

(52) U.S. Cl. CPC H02M 3/158; H02M 1/44; H03K 4/06

(57) ABSTRACT

A clock signal generation circuit (10) includes: a first modulation signal generation circuit (11) that generates a first modulation signal (Sm1) having a first frequency (f1); a second modulation signal generation circuit (12) that generates a second modulation signal (Sm2) having a second frequency (f2) lower than the first frequency; a signal combining circuit (13) that generates a composite modulation signal (Smc) by combining the first modulation signal and the second modulation signal; and an oscillator (14) that generates a clock signal (CLK) having a frequency according to the composite modulation signal.

### CROSS-REFERENCE TO RELATED APPLICATION

This application claims the priority benefit of Japanese application serial no. 2024-140816, filed on Aug. 22, 2024. The entirety of the above-mentioned patent application is hereby incorporated by reference herein and made a part of this specification.

### Technical Field

The disclosure relates to a clock signal generation circuit, a power supply control device, and a switching power supply device.

### Background Technology

Clock signal generation circuits that generate clock signals are incorporated into various devices. For example, there are switching power supply devices (DC/DC converters) that perform DC/DC conversion using the frequency of a clock signal as a switching frequency. When the frequency of the clock signal is fixed, the radiated noise at the frequency becomes large. Spectrum spreading technology exists as a technology to suppress the influence of radiated noise. With spectrum spreading technology, noise is spread over a wide band, making it possible to effectively suppress the influence of noise.

### RELATED ART DOCUMENT

### Patent Document

[Patent Document 1] International Publication No. 2023/286459

However, there is room for improvement in the current spectrum spreading technology related to clock signals.

### SUMMARY

A clock signal generation circuit according to one aspect of the disclosure includes: a first modulation signal generation circuit configured to generate a first modulation signal having a first frequency; a second modulation signal generation circuit configured to generate a second modulation signal having a second frequency lower than the first frequency; a signal combining circuit configured to generate a composite modulation signal by combining the first modulation signal and the second modulation signal; and an oscillator configured to generate a clock signal having a frequency according to the composite modulation signal.

### BRIEF DESCRIPTION OF THE DRAWINGS

FIG. 1 is an overall configuration diagram of the switching power supply device according to an embodiment of the disclosure.

FIG. 2 is a waveform diagram of the first modulation signal according to an embodiment of the disclosure.

FIG. 3 is a waveform diagram of the second modulation signal according to an embodiment of the disclosure.

FIG. 4 is a waveform diagram of the composite modulation signal according to an embodiment of the disclosure.

FIG. 5 is a configuration diagram of the first modulation signal generation circuit according to an embodiment of the disclosure.

FIG. 6 is a configuration diagram of the signal combining circuit according to an embodiment of the disclosure.

FIG. 7 is a waveform diagram of the modulation current as the second modulation signal according to an embodiment of the disclosure.

FIG. 8 is a circuit configuration diagram for generating the composite modulation signal according to an embodiment of the disclosure.

FIG. 9 is an explanatory diagram of the noise reduction effect according to an embodiment of the disclosure.

FIG. 10 is a schematic configuration diagram of the switching power supply device according to the second example belonging to an embodiment of the disclosure.

FIG. 11 is an external perspective view of the power supply control device according to the second example belonging to an embodiment of the disclosure.

FIG. 12 is a detailed configuration diagram of the switching power supply device according to the second example belonging to an embodiment of the disclosure.

FIG. 13 is a diagram showing the relationship between a clock signal and two gate signals according to the second example belonging to an embodiment of the disclosure.

FIG. 14 is a configuration diagram of the switching power supply device according to the first reference configuration.

FIG. 15 is a configuration diagram of the switching power supply device according to the second reference configuration.

### DESCRIPTION OF THE EMBODIMENTS

Prior to describing the switching power supply device according to an embodiment of the disclosure, switching power supply devices according to first and second reference configurations will be described.

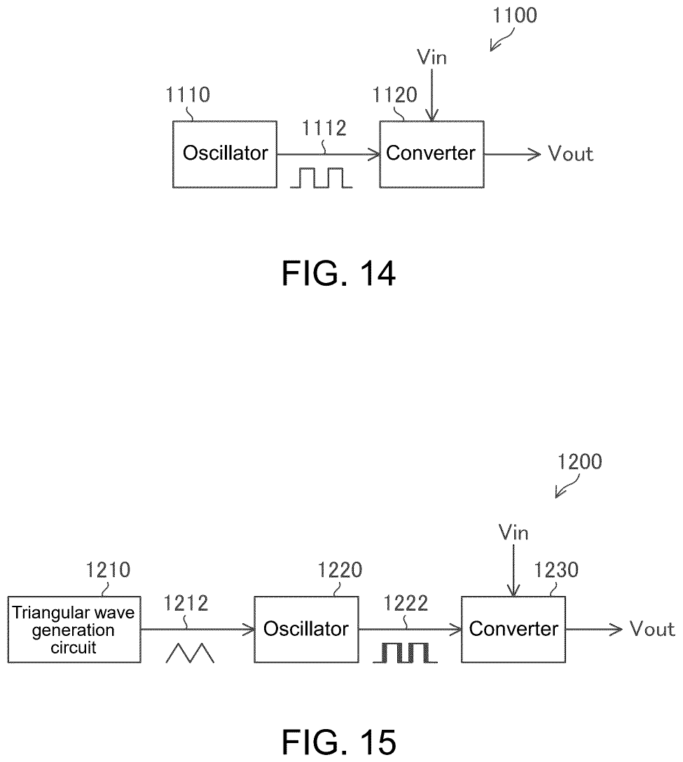

FIG. 14 shows the configuration of a switching power supply device 1100 according to the first reference configuration. The switching power supply device 1100 includes an oscillator 1110 and a converter 1120. In the switching power supply device 1100, a frequency-fixed clock signal 1112 output from the oscillator 1110 is supplied to the converter 1120. The converter 1120 generates an output voltage Vout by performing a switching operation on an input voltage Vin using the frequency of the clock signal 1112 as a switching frequency. The input voltage Vin and the output voltage Vout are DC voltages different from each other. In the configuration of FIG. 14, large noise is generated at the frequency of the clock signal 1112, and this noise becomes a factor in the characteristic degradation of EMI (Electro Magnetic Interference).

FIG. 15 shows the configuration of a switching power supply device 1200 according to the second reference configuration. The switching power supply device 1200 includes a triangular wave generation circuit 1210, an oscillator 1220, and a converter 1230. A triangular wave signal 1212 is output from the triangular wave generation circuit 1210. The oscillator 1220 supplies a clock signal 1222 having a frequency according to the value of the triangular wave signal 1212 to the converter 1230. The converter 1230 is a circuit similar to the converter 1120 in FIG. 14, and generates an output voltage Vout from an input voltage Vin by a switching operation synchronized with the clock signal 1222. In the second reference configuration, radiated noise at the switching frequency is reduced compared to the first reference configuration because the frequency of the clock signal 1222 is modulated based on the triangular wave signal 1212. However, in the second reference configuration, new noise is generated at the frequency of the triangular wave and at the frequency of the harmonics of the triangular wave, which becomes a new factor in the characteristic degradation of EMI.

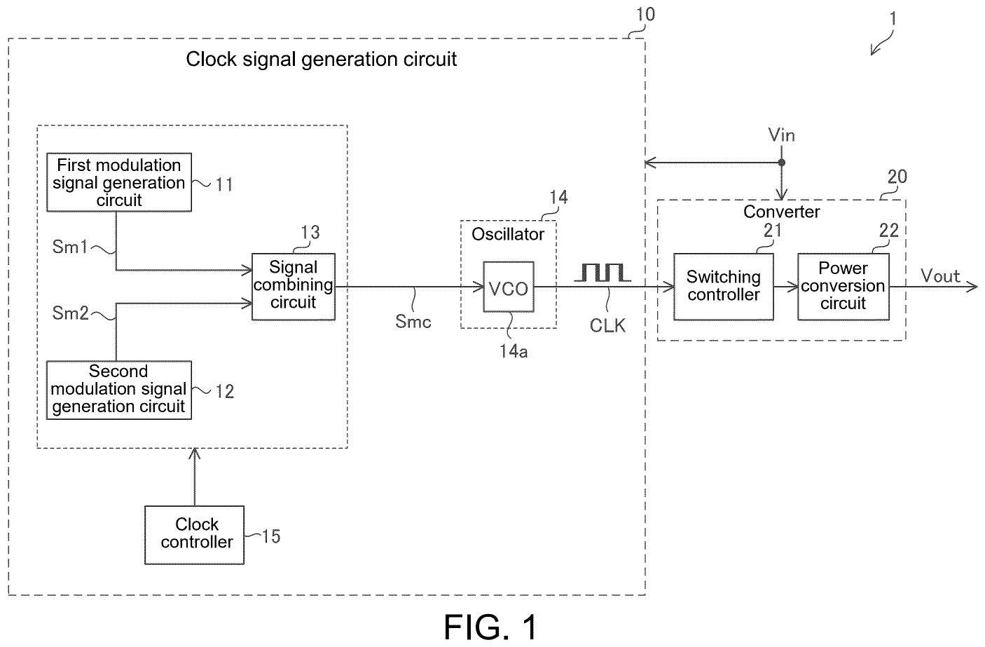

Embodiments of the disclosure in view of these circumstances are shown below. In each figure referenced in the embodiments of the disclosure, the same parts are given the same reference numerals, and duplicate descriptions of the same parts are omitted in principle. In this specification, for the sake of simplification, information, signals, physical quantities, functional parts, circuits, elements, or components are indicated by symbols or reference numerals referring thereto, and the names of the information, signals, physical quantities, functional parts, circuits, elements, or components corresponding to the symbols or reference numerals may be omitted or abbreviated. For example, the first modulation signal generation circuit referred to later by “11” (see FIG. 1) may be denoted as first modulation signal generation circuit 11, or may be abbreviated as modulation signal generation circuit 11, generation circuit 11, or circuit 11, but all of these refer to the same part.

Explanation is provided for several terms used in the description of the embodiments of the disclosure. Ground refers to a reference conductor having a reference potential of 0V (zero volts) or refers to the potential of 0V itself. The reference conductor may be formed using a conductor such as metal. The potential of 0V may also be called the ground potential. In the embodiments of the disclosure, a voltage shown without setting a specific reference represents the potential as seen from the ground. Level refers to the level (height) of a potential, and for any signal or voltage of interest, a high level has a higher potential than a low level. In any signal or voltage of interest, the switching from low level to high level may be called a rising edge, and the switching from high level to low level may be called a falling edge.

For any transistor configured as a FET (field-effect transistor) exemplified by a MOSFET, on state refers to a state in which there is conduction between drain and source of the transistor, and off state refers to a state in which there is no conduction between drain and source of the transistor (blocked state). The same applies to transistors not classified as FETs. Unless otherwise specified, a MOSFET is understood to be an enhancement type MOSFET. MOSFET is an abbreviation for “metal-oxide-semiconductor field-effect transistor”. Also, unless otherwise specified, in any MOSFET, the back gate may be considered to be shorted to the source. In the following, for any transistor, the on state and off state may be simply expressed as on and off.

For any signal having a signal level at high level or low level, the period during which the level of the signal is set to high level is called a high level period, and the period during which the level of the signal is set to low level is called a low level period. The same applies to any voltage having a voltage level at high level or low level.

Connection between multiple parts forming a circuit, such as any circuit element, wiring, and node, may be understood to refer to electrical connection, unless otherwise specified.

In a case where any two voltages to be compared are voltage v1 and voltage v2, “v1>v2” indicates that voltage v1 is higher than voltage v2, “v1<v2” indicates that voltage v1 is lower than voltage v2, and “v1=v2” indicates that the value of voltage v1 is the same as the value of voltage v2. The same applies to other expressions including physical quantities other than voltage.

FIG. 1 shows a schematic overall configuration of a switching power supply device 1 according to an embodiment of the disclosure. The switching power supply device 1 includes a clock signal generation circuit 10 and a converter 20. An input voltage Vin is supplied to the switching power supply device 1 from a DC voltage source (not shown). The switching power supply device 1 generates an output voltage Vout by power-converting the input voltage Vin (that is, converting the input voltage Vin into the output voltage Vout). The input voltage Vin and the output voltage Vout are positive DC voltages different from each other. The output voltage Vout may be lower than the input voltage Vin, or may be higher than the input voltage Vin. That is, the switching power supply device 1 may be a buck type switching power supply device, a boost type switching power supply device, or a buck-boost type switching power supply device. The clock signal generation circuit 10 and the converter 20 operate based on the input voltage Vin. Some circuits in the clock signal generation circuit 10 and the converter 20 may operate based on an internal power supply voltage generated based on the input voltage Vin.

The clock signal generation circuit 10 includes a first modulation signal generation circuit 11, a second modulation signal generation circuit 12, a signal combining circuit 13, an oscillator 14, and a clock controller 15.

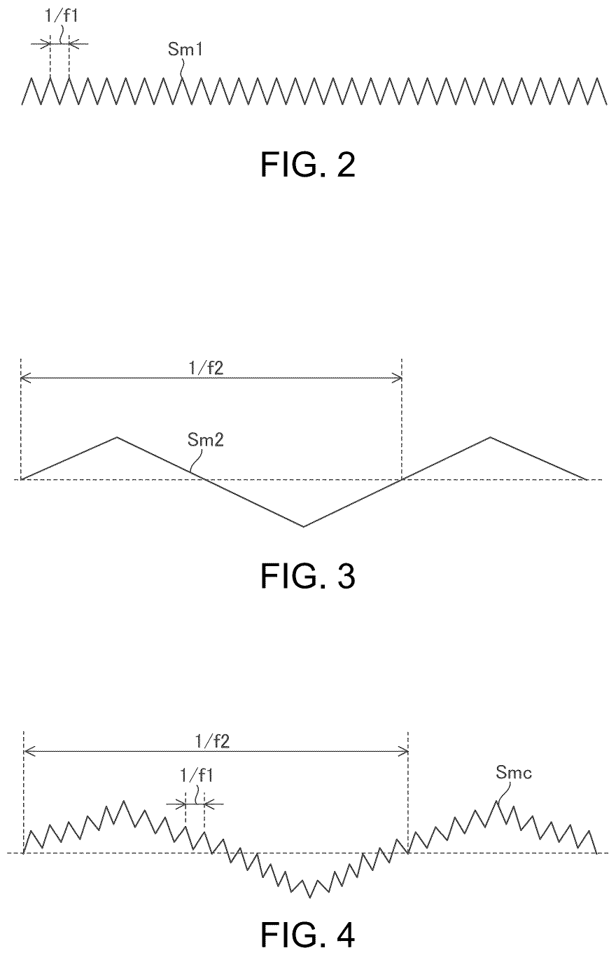

The first modulation signal generation circuit 11 generates a modulation signal Sm1, which is a first modulation signal (first signal for modulation), and outputs the modulation signal Sm1 to the signal combining circuit 13. The modulation signal Sm1 is a pulsating signal having a predetermined frequency f1, and therefore the signal value of the modulation signal Sm1 varies with time. Here, to be more specific, as shown in FIG. 2, the modulation signal Sm1 is assumed to be a triangular wave signal having the frequency f1. However, the triangular wave signal as the modulation signal Sm1 does not necessarily have a waveform of a strictly triangular wave shape, and may have a waveform approximating a triangular wave. The modulation signal Sm1 may be a sine wave signal having a sine wave shape, a pseudo-sine wave signal having a waveform shape approximating a sine wave shape, or a mixed signal obtained by mixing a triangular wave signal and a sine wave signal.

The second modulation signal generation circuit 12 generates a modulation signal Sm2, which is a second modulation signal (second signal for modulation), and outputs the modulation signal Sm2 to the signal combining circuit 13. The modulation signal Sm2 is a pulsating signal having a predetermined frequency f2, and therefore the signal value of the modulation signal Sm2 varies with time. Here, to be more specific, as shown in FIG. 3, the modulation signal Sm2 is assumed to be a triangular wave signal having the frequency f2. However, the triangular wave signal as the modulation signal Sm2 does not necessarily have a waveform of a strictly triangular wave shape, and may have a waveform approximating a triangular wave. The modulation signal Sm2 may be a sine wave signal having a sine wave shape, a pseudo-sine wave signal having a waveform shape approximating a sine wave shape, or a mixed signal obtained by mixing a triangular wave signal and a sine wave signal.

The frequency f2 is lower than the frequency f1. For example, while the frequency f1 has a frequency within the frequency range of 1 kHz to 10 kHz (or a frequency in the vicinity thereof), the frequency f2 has a frequency within the range of several tens of Hz to several hundreds of Hz (or a frequency in the vicinity thereof). The values mentioned here are merely examples, and as long as the frequency f2 is lower than the frequency f1, the values of the frequencies f1 and f2 are arbitrary.

The signal combining circuit 13 generates a composite modulation signal Smc by combining (in other words, mixing) the modulation signal Sm1 and the modulation signal Sm2. The signal combining circuit 13 outputs the composite modulation signal Smc to the oscillator 14. FIG. 4 shows a waveform example of the composite modulation signal Smc. The composite modulation signal Smc has a signal component of the frequency f1 and a signal component of the frequency f2.

The oscillator 14 generates and outputs a clock signal CLK having a frequency according to the composite modulation signal Smc. The clock signal CLK is a rectangular wave signal that alternately has high level and low level. The frequency of the clock signal CLK is denoted as frequency f_{CLK.}

The oscillator 14 includes a VCO 14a which is a voltage controlled oscillator. The composite modulation signal Smc is input to the VCO 14a. The composite modulation signal Smc is an analog voltage signal. The VCO 14a converts the composite modulation signal Smc into the frequency f_{CLK}, and generates and outputs the clock signal CLK having the frequency f_{CLK}. The frequency f_{CLK} increases with an increase in the voltage value of the composite modulation signal Smc, and decreases with a decrease in the voltage value of the composite modulation signal Smc. The frequency f_{CLK} is modulated (spread) according to the voltage value of the composite modulation signal Smc based on the center frequency of the clock signal CLK. The amount of change in the frequency f_{CLK} relative to the amount of unit change in the voltage value of the composite modulation signal Smc may be constant throughout the entire range of change of the frequency f_{CLK}. The frequency f_{CLK} and the composite modulation signal Smc may have a direct proportion relationship. The oscillator 14 supplies the clock signal CLK to the converter 20.

The clock controller 15 controls the operations of the first modulation signal generation circuit 11, the second modulation signal generation circuit 12, and the signal combining circuit 13. The operation of the oscillator 14 may also be controlled by the clock controller 15. The clock controller 15 operates in synchronization with a master clock signal (not shown). The master clock signal has a higher frequency than the clock signal CLK.

The converter 20 receives the input voltage Vin from a DC voltage source (not shown), and generates and outputs the output voltage Vout by DC/DC conversion of the input voltage Vin. The converter 20 includes a switching controller 21 and a power conversion circuit 22. The clock signal CLK is input to the converter 20. The converter 20 converts the input voltage Vin into the output voltage Vout by performing switching control using the frequency of the clock signal CLK as a switching frequency. More specifically, the power conversion circuit 22 has an output stage circuit provided between the application terminal of the input voltage Vin and the application terminal of the output voltage Vout, and the output stage circuit includes at least an output transistor. The switching controller 21 generates the output voltage Vout through switching the output transistor using the frequency f_{CLK} of the clock signal CLK as the switching frequency.

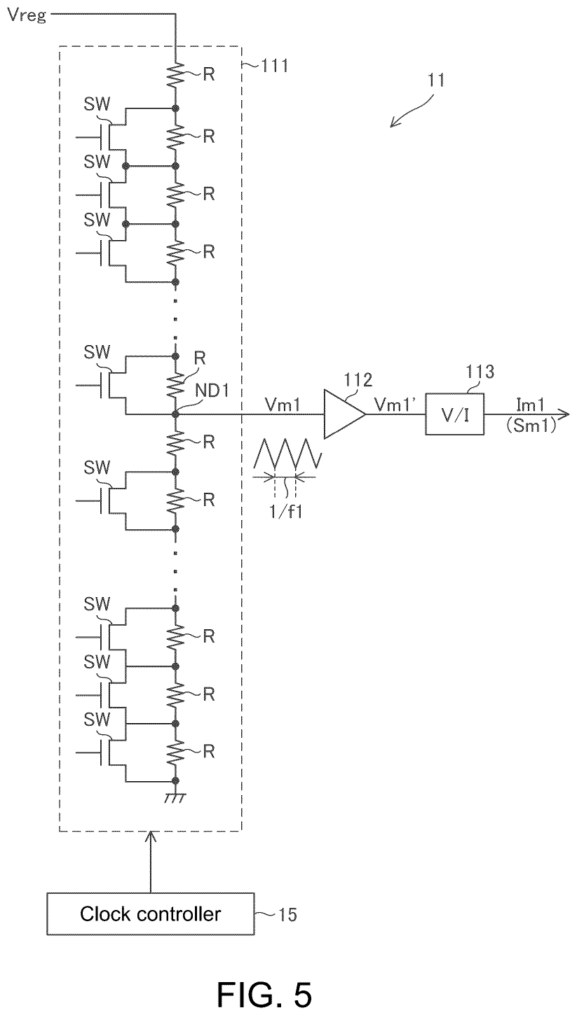

FIG. 5 shows the internal configuration of the first modulation signal generation circuit 11. The modulation signal generation circuit 11 includes a ladder resistance circuit 111, a buffer circuit 112, and a VI conversion circuit 113.

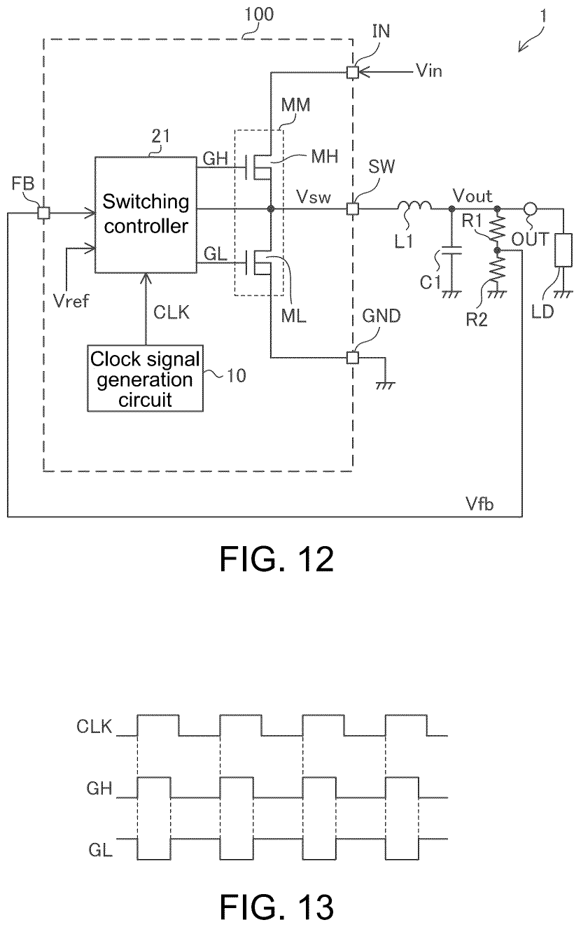

An internal voltage Vreg, which is a predetermined positive DC voltage, is supplied to the ladder resistance circuit 111. The internal voltage Vreg is generated based on the input voltage Vin within the clock signal generation circuit 10 or within a device (for example, the power supply control device 100 described later; see FIG. 12) that includes the clock signal generation circuit 10. The ladder resistance circuit 111 has a series circuit of first to m-th voltage dividing resistors R, and includes switching elements SW connected in parallel to the voltage dividing resistors R for each voltage dividing resistor R. However, for some of the first to m-th voltage dividing resistors R, the switching elements SW may not be connected in parallel. m has an integer value sufficiently larger than 2. The switching elements SW may be configured by MOSFETs.

The series circuit of the first to m-th voltage dividing resistors R is provided between the application terminal of the internal voltage Vreg and the ground. The first terminal of the first voltage dividing resistor R is connected to the application terminal of the internal voltage Vreg. The second terminal of the i-th voltage dividing resistor R is connected to the first terminal of the (i+1)-th voltage dividing resistor R. The second terminal of the m-th voltage dividing resistor R is connected to the ground. i represents any natural number. However, the upper limit of the symbol “i” in the (i+1)-th voltage dividing resistor R is (m-1).

An intermediate node ND1 is set for the series circuit of the first to m-th voltage dividing resistors R. The intermediate node ND1 is, for example, a connection node between the second terminal of the (2/m)-th voltage dividing resistor R and the first terminal of the ((2/m)+1)-th voltage dividing resistor R (however, it is assumed that m is an even number). A voltage division of the internal voltage Vreg is generated at the intermediate node ND1 as a modulation voltage Vm1. The clock controller 15 generates a triangular wave voltage that periodically varies within a voltage range from a predetermined lower limit voltage to a predetermined upper limit voltage as the modulation voltage Vm1 by individually controlling on or off of each switching element SW in the ladder resistance circuit 111. The upper limit voltage is higher than the lower limit voltage. The clock controller 15 sets the frequency of the modulation voltage Vm1 to the frequency f1 by varying the voltage division ratio (the voltage division ratio in the ladder resistance circuit 111) for generating the modulation voltage Vm1 from the internal voltage Vreg at the frequency f1.

The input terminal of the buffer circuit 112 is connected to the intermediate node ND1. The buffer circuit 112 receives the modulation voltage Vm1 with a sufficiently high input impedance, and outputs a modulation voltage Vm1′ having the same voltage value as the modulation voltage Vm1 from the output terminal thereof with a sufficiently low output impedance. The buffer circuit 112 can be formed with a voltage follower circuit. The modulation voltage Vm1′ is input to the VI conversion circuit 113. The VI conversion circuit 113 performs voltage/current conversion that converts the modulation voltage Vm1′, which is an analog voltage signal, into a modulation current Im1, which is an analog current signal. The modulation current Im1 has a current value that is in direct proportion to the value of the modulation voltage Vm1′. That is, Im1=k_{VI}×Vm1′. The modulation current Im1 has a current waveform of a triangular wave shape (strictly speaking, a current waveform similar to a triangular wave). The frequency of the modulation current Im1 is the frequency f1. k_{VI} is a predetermined coefficient with the unit [ampere/volt]. The modulation current Im1 is output from the first modulation signal generation circuit 11 as a modulation signal Sm1.

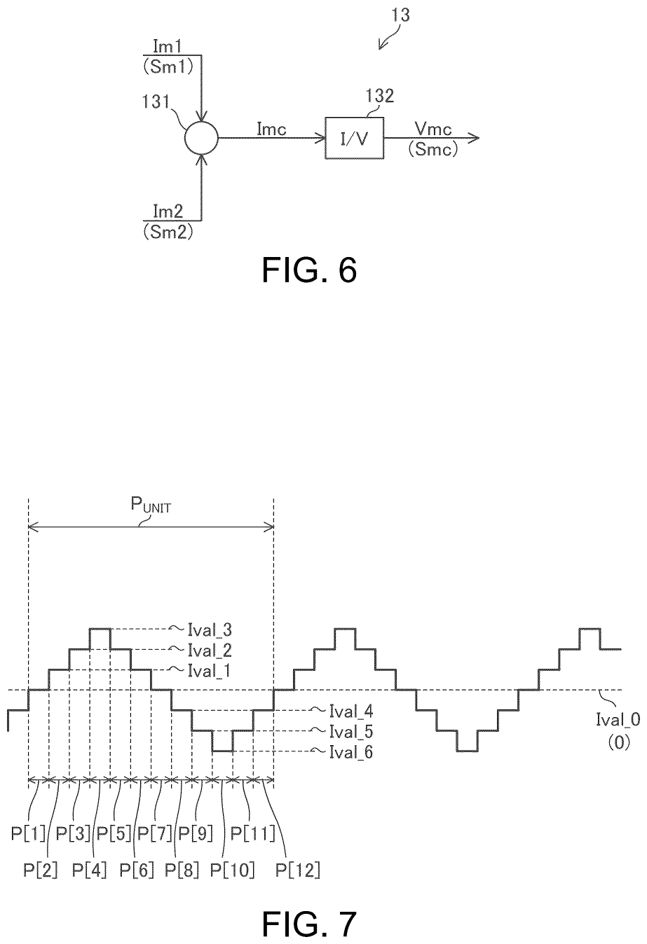

FIG. 6 shows the internal configuration of the signal combining circuit 13. The signal combining circuit 13 includes a linear operation circuit 131 and an IV conversion circuit 132. The modulation current Im1 as the modulation signal Sm1 from the first modulation signal generation circuit 11 is input to the linear operation circuit 131. On the other hand, a modulation current Im2 from the second modulation signal generation circuit 12 is also input to the linear operation circuit 131. The modulation current Im2 corresponds to the modulation signal Sm2. Similar to the modulation current Im1, the modulation current Im2 has a current waveform of a triangular wave shape (strictly speaking, a current waveform similar to a triangular wave). However, the frequency of the modulation current Im2 is the frequency f2.

The linear operation circuit 131 is an analog circuit that generates and outputs a composite current Imc which is a current obtained by combining the modulation current Im1 and the modulation current Im2. “Imc=Im1+Im2”. However, while the modulation current Im1 always has a positive current value, the modulation current Im2 may have a positive current value or a negative current value.

The IV conversion circuit 132 performs current/voltage conversion that converts the composite current Imc, which is an analog current signal, into a composite voltage Vmc, which is an analog voltage signal. The composite voltage Vmc has a voltage value in direct proportion to the value of the composite current Imc. That is, “Vmc=k_{IV}×Imc”. k_{IV} is a predetermined coefficient with the unit of [volt/ampere]. The composite voltage Vmc is the composite modulation signal Smc, and is supplied to the oscillator 14.

FIG. 7 shows the waveform of the modulation current Im2. The period of one cycle in the modulation current Im2 is called a unit period P_{UNIT}. The length of the unit period P_{UNIT} coincides with the reciprocal of the frequency f2. The unit period P_{UNIT} is a composite period of periods P[1] to P[12]. Based on the master clock signal, the unit period P_{UNIT} and the periods P[1] to P[12] are set and defined by the clock controller 15. For any natural number i, periods P[i] and P[i+1] are periods adjacent to each other, and period P[i+1] is a period after period P[i]. When period P[12] in a certain unit period P_{UNIT} ends, period P[1] in the next unit period P_{UNIT} begins. The lengths of periods P[1] to P[12] are equal to each other. Therefore, the length of each of periods P[1] to P[12] is 1/12 of the length of the unit period P_{UNIT}. However, among the lengths of periods P[1] to P[12], some lengths may differ from other lengths. That is, the length of period P[i_{A}] may differ from the length of period P[i_{B}] (where i_{A} and i_{B} represent different natural numbers that are 12 or less).

The current value of the modulation current Im2 becomes one of the seven current values Ival_0 to Ival_6. The current values Ival_0 to Ival_6 are seven predetermined current values that satisfy “Ival_6<Ival_5<Ival_4<Ival_0<Ival_1<Ival_2<Ival_3”. Among the current values Ival_0 to Ival_6, the current values Ival_1, Ival_2, and Ival_3 have positive current values, and the current values Ival_4, Ival_5, and Ival_6 have negative current values. Here, the current value Ival_0 is assumed to be zero (zero ampere). However, the current value Ival_0 may be a positive or negative small value.

In periods P[1] and P[7], the modulation current Im2 has the current value Ival_0.

In periods P[2] and P[6], the modulation current Im2 has the current value Ival_1.

In periods P[3] and P[5], the modulation current Im2 has the current value Ival_2.

In period P[4], the modulation current Im2 has the current value Ival_3.

In periods P[8] and P[12], the modulation current Im2 has the current value Ival_4.

In periods P[9] and P[11], the modulation current Im2 has the current value Ival_5.

In period P[10], the modulation current Im2 has the current value Ival_6.

That is, in each unit period P_{UNIT}, the modulation current Im2 increases from period P[1] to period P[4], then decreases from period P[4] to period P[10], and thereafter increases from period P[10] to period P[12].

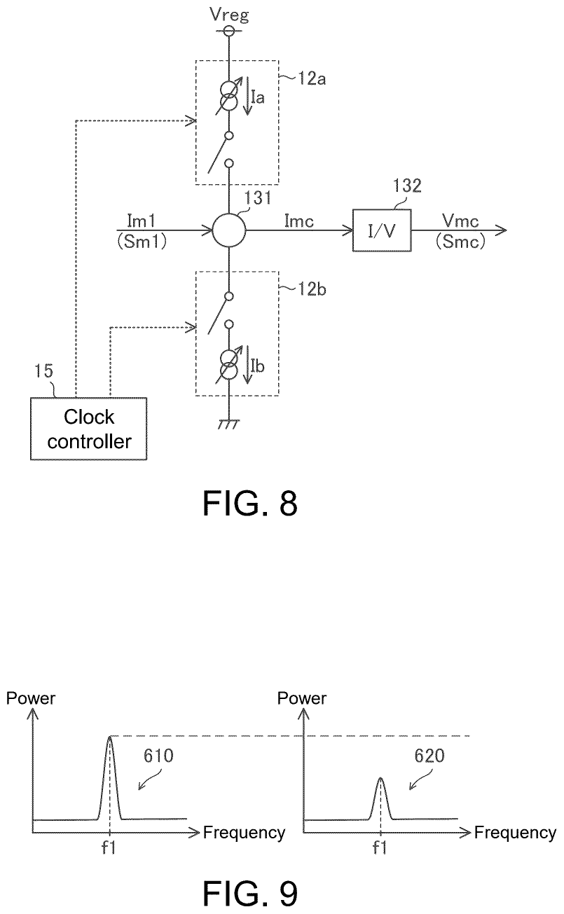

Referring to FIG. 8, the second modulation signal generation circuit 12 includes variable current sources 12a and 12b. The variable current source 12a is connected to the linear operation circuit 131, and supplies an addition current Ia to the linear operation circuit 131. However, as will be described later, there exist periods in which the addition current Ia is set to zero. The variable current source 12b is connected to the linear operation circuit 131, and draws a subtraction current Ib from the linear operation circuit 131. However, as will be described later, there exist periods in which the subtraction current Ib is set to zero. Both the variable current sources 12a and 12b are driven based on the internal voltage Vreg. The variable current source 12a has the ability to change the magnitude of the addition current Ia, and the variable current source 12b has the ability to change the magnitude of the subtraction current Ib.

The clock controller 15 controls the presence or absence of the addition current Ia between the variable current source 12a and the linear operation circuit 131, as well as controls the magnitude of the addition current Ia in the case of generating the addition current Ia between the variable current source 12a and the linear operation circuit 131. The clock controller 15 controls the presence or absence of the subtraction current Ib between the variable current source 12b and the linear operation circuit 131, as well as controls the magnitude of the subtraction current Ib in the case of generating the subtraction current Ib between the variable current source 12b and the linear operation circuit 131.

The clock controller 15 switches and sets the magnitude of the addition current Ia to one of zero and absolute values |Ival_1|, |Ival_2|, and |Ival_3|. The clock controller 15 switches and sets the magnitude of the subtraction current Ib to one of zero and absolute values |Ival_4|, |Ival_5|, and |Ival_6|. The absolute values |Ival_1| to |Ival_6| represent the absolute values of the current values Ival_1 to Ival_6, respectively. However, since the current values Ival_1 to Ival_3 have positive polarity, the absolute values |Ival_1| to |Ival_3| are equal to the current values Ival_1 to Ival_3, respectively.

The modulation current Im2 is composed of the addition current Ia and the subtraction current Ib. The linear operation circuit 131 generates the composite current Imc by combining the modulation current Im1 with the addition current Ia or the subtraction current Ib. However, in this combination, the addition current Ia is added to the modulation current Im1, while the subtraction current Ib is drawn from the modulation current Im1. That is, “Imc=Im1+Ia−Ib”.

In periods P[1] and P[7], the clock controller 15 sets both the magnitude of the addition current Ia and the magnitude of the subtraction current Ib to zero. Therefore, in periods P[1] and P[7], “Imc=Im1” (that is, the composite current Imc is equal to the modulation current Im1).

In periods P[2] and P[6], the clock controller 15 sets the magnitude of the addition current Ia to the absolute value |Ival_1| and sets the magnitude of the subtraction current Ib to zero. Therefore, in periods P[2] and P[6], “Imc=Im1+Ia”, and the composite current Imc is larger than the modulation current Im1 by the absolute value |Ival_1|.

In periods P[3] and P[5], the clock controller 15 sets the magnitude of the addition current Ia to the absolute value |Ival_2| and sets the magnitude of the subtraction current Ib to zero. Therefore, in periods P[3] and P[5], “Imc=Im1+Ia”, and the composite current Imc is larger than the modulation current Im1 by the absolute value |Ival_2|.

In period P[4], the clock controller 15 sets the magnitude of the addition current Ia to the absolute value |Ival_3| and sets the magnitude of the subtraction current Ib to zero. Therefore, in period P[4], “Imc=Im1+Ia”, and the composite current Imc is larger than the modulation current Im1 by the absolute value |Ival_3|.

In periods P[8] and P[12], the clock controller 15 sets the magnitude of the subtraction current Ib to the absolute value |Ival_4| and sets the magnitude of the addition current Ia to zero. Therefore, in periods P[8] and P[12], “Imc=Im1−Ib”, and the composite current Imc is smaller than the modulation current Im1 by the absolute value |Ival_4|.

In periods P[9] and P[11], the clock controller 15 sets the magnitude of the subtraction current Ib to the absolute value |Ival_5| and sets the magnitude of the addition current Ia to zero. Therefore, in periods P[9] and P[11], “Imc=Im1−Ib”, and the composite current Imc is smaller than the modulation current Im1 by the absolute value |Ival_5|.

In period P[10], the clock controller 15 sets the magnitude of the subtraction current Ib to the absolute value |Ival_6| and sets the magnitude of the addition current Ia to zero. Therefore, in period P[10], “Imc=Im1−Ib”, and the composite current Imc is smaller than the modulation current Im1 by the absolute value |Ival_6|. In addition, the lower limit value of the modulation current Im1 is larger than the absolute value |Ival_6|. Therefore, the composite current Imc does not become zero or less.

In this way, the signal combining circuit 13 generates the composite current Imc by adding the addition current Ia to the modulation current Im1 or subtracting the subtraction current Ib from the modulation current Im1, and generates the composite voltage Vmc as the composite modulation signal Smc by converting the composite current Imc into a voltage signal. At this time, under the control of the clock controller 15, the addition current Ia and the subtraction current Ib vary according to the frequency f2.

Specifically, the clock controller 15 repeatedly sets the unit period P_{UNIT} that includes an addition period in which the addition current Ia is added to the modulation current Im1 and a subtraction period in which the subtraction current Ib is subtracted from the modulation current Im1. By the clock controller 15, the repetition frequency of multiple unit periods P_{UNIT} is set to the frequency f2. In the example shown in FIG. 7, among the addition period and the subtraction period in each unit period P_{UNIT}, the subtraction period is provided after the addition period. However, in each unit period P_{UNIT}, the addition period may be provided after the subtraction period.

Periods P[2] to P[6] belong to the addition period, and periods P[8] to P[12] belong to the subtraction period. In the addition period, the modulation current Im2 is composed of the addition current Ia, while in the subtraction period, the modulation current Im2 is composed of the subtraction current Ib. Periods P[1] and P[7] do not belong to either the addition period or the subtraction period. However, either one or both of periods P[1] and P[7] may be modified to belong to the addition period or the subtraction period.

Under the control of the clock controller 15, the second modulation signal generation circuit 12 (12a, 12b) monotonically increases and then monotonically decreases the addition current Ia in the addition period (periods P[2] to P[6]), and monotonically increases and then monotonically decreases the subtraction current Ib in the subtraction period (periods P[8] to P[12]). This enables the modulation current Im2 to be gradually changed.

According to the method of this embodiment, the frequency f_{CLK} of the clock signal CLK is modulated (spread) at the frequency f1 of the modulation signal Sm1 as well as modulated (spread) at the frequency f2 of the modulation signal Sm2. Therefore, as shown in FIG. 9, reduction of noise generated at the frequency f1 is achieved, and improvement of EMI characteristics can be expected. In FIG. 9, waveform 610 schematically shows the power spectrum of generated noise in the second reference configuration of FIG. 15. In FIG. 9, waveform 620 schematically shows the power spectrum of generated noise in the configuration of FIG. 1. By improving the second reference configuration of FIG. 15 to the configuration of FIG. 1, the generated noise at the frequency f1 can be significantly reduced. Although not specifically shown, in comparison with the second reference configuration of FIG. 15, the configuration of FIG. 1 can reduce the generated noise in a wide range of bands including not only around the frequency f1 but also the switching frequency (f_{CLK}) of the output transistor.

It is also considered to achieve spectrum spreading by superimposing a random number signal on a triangular wave signal, but the circuit required for random number generation is large in scale. With the method of this embodiment, a good spectrum spreading effect can be obtained by a simple configuration (small-scale circuit configuration).

This embodiment includes the following first to fourth examples. The matters described above in this embodiment are applicable to each of the following examples unless otherwise specified and unless contradictory. In each example, if there are matters that contradict the above-described matters, the description in each example may take precedence. Also, unless contradictory, matters described in any of the multiple examples shown below can be applied to any other example (that is, it is also possible to combine any two or more examples from among the multiple examples).

### First Example

The first example will be described. The variable current source 12a switches the magnitude of the addition current Ia in x stages during the addition period. In the above-described configuration, “x=3”, but x can be any integer of 2 or more. Similarly, the variable current source 12b switches the magnitude of the subtraction current Ib in y stages during the subtraction period. In the above-described configuration, “y=3”, but y can be any integer of 2 or more.

### Second Example

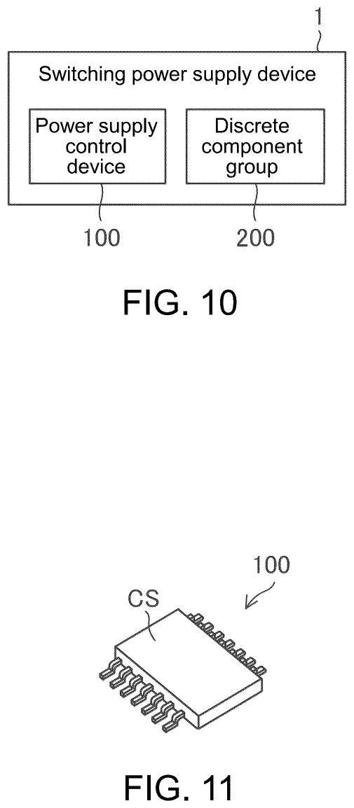

The second example will be described. FIG. 10 shows a schematic configuration of a switching power supply device 1 according to the second example. The switching power supply device 1 in FIG. 10 includes a power supply control device 100 and a discrete component group 200. The discrete component group 200 includes multiple discrete components that are externally connected to the power supply control device 100.

FIG. 11 shows an external perspective view of the power supply control device 100. The power supply control device 100 is an electronic component that includes a semiconductor chip having a semiconductor integrated circuit formed on a semiconductor substrate, a housing CS (package) that accommodates the semiconductor chip, and multiple external terminals that are exposed from the housing CS to the outside of the power supply control device 100. The power supply control device 100 is formed by sealing the semiconductor chip in the housing CS made of resin. The number of external terminals of the power supply control device 100 and the type of the housing CS of the power supply control device 100 shown in FIG. 11 are merely examples, and may be designed arbitrarily.

The clock signal generation circuit 10 and the switching controller 21 (see FIG. 1) described above are provided inside the power supply control device 100. A part of the power conversion circuit 22 (such as output transistor) is provided inside the power supply control device 100, and the remaining part of the power conversion circuit 22 is formed by the discrete component group 200.

FIG. 12 shows a detailed configuration of the switching power supply device 1 according to the second example. The switching power supply device 1 in FIG. 12 includes the power supply control device 100, as well as a coil L1, an output capacitor C1, and feedback resistors R1 and R2 as components of the discrete component group 200. In the configuration of FIG. 12, the power conversion circuit 22 (see FIG. 1) is configured by an output stage circuit MM, the coil L1, and the output capacitor C1. The switching power supply device 1 in FIG. 12 is configured as a buck type switching power supply device (DC/DC converter) that generates a desired output voltage Vout from an input voltage Vin supplied from a DC voltage source (not shown). The output voltage Vout occurs at an output terminal OUT. That is, the output terminal OUT is the application terminal of the output voltage Vout (a terminal to which the output voltage Vout is applied). The output voltage Vout is supplied to a load LD connected to the output terminal OUT.

Except in transient states, the input voltage Vin and the output voltage Vout are positive DC voltages, and the output voltage Vout is lower than the input voltage Vin. For example, when the input voltage Vin is 12V, the output voltage Vout can be stabilized at a desired positive voltage value less than 12V (for example, 3.3V or 5V) by adjusting the resistance values of the feedback resistors R1 and R2.

FIG. 12 shows, as part of a group of external terminals provided in the power supply control device 100, an input terminal IN, a switch terminal SW, a ground terminal GND, and a feedback terminal FB.

The external configuration of the power supply control device 100 will be described. The input voltage Vin is supplied to the input terminal IN from a DC voltage source (not shown) provided external to the power supply control device 100. The coil L1 is interposed in series between the switch terminal SW and the output terminal OUT. That is, the first terminal of the coil L1 is connected to the switch terminal SW, and the second terminal of the coil L1 is connected to the output terminal OUT. In addition, the output terminal OUT is connected to the ground via the output capacitor C1. That is, the first terminal of the output capacitor C1 is connected to the output terminal OUT, and the second terminal of the output capacitor C1 is connected to the ground. Furthermore, the output terminal OUT is connected to the first terminal of the feedback resistor R1, the second terminal of the feedback resistor R1 is connected to the first terminal of the feedback resistor R2, and the second terminal of the feedback resistor R2 is connected to the ground. A feedback voltage Vfb occurs at the connection node between the feedback resistors R1 and R2. The connection node between the feedback resistors R1 and R2 is connected to the feedback terminal FB, thereby inputting the feedback voltage Vfb to the feedback terminal FB. The ground terminal GND is connected to the ground.

The internal configuration of the power supply control device 100 will be described. The power supply control device 100 includes an output stage circuit MM, a switching controller 21, and a clock signal generation circuit 10.

The output stage circuit MM includes transistors MH and ML. In the configuration example of FIG. 12, the transistors MH and ML are configured by N-channel type MOSFETs. The transistors MH and ML are a pair of switching elements connected in series between the input terminal IN and the ground terminal GND (in other words, ground). The transistor MH functions as an output transistor, and the transistor ML functions as a rectifier element (synchronous rectification transistor). The transistor MH is provided on the higher potential side than the transistor ML. Specifically, the drain of the transistor MH is connected to the input terminal IN, which is the application terminal of the input voltage Vin, and receives the supply of the input voltage Vin. The source of the transistor MH and the drain of the transistor ML are commonly connected to the switch terminal SW. The source of the transistor ML is connected to the ground terminal GND (therefore connected to the ground). However, in some cases, a resistor for current detection may be inserted between the source of the transistor ML and the ground terminal GND.

The output stage circuit MM is switching-controlled by the switching controller 21. In the switching control of the output stage circuit MM, the transistors MH and ML are switched so that the transistors MH and ML alternately turn on and off. A switch voltage Vsw of a rectangular wave shape appears at the switch terminal SW due to the switching control of the output stage circuit MM. The coil L1 and the output capacitor C1 constitute a rectification smoothing circuit that rectifies and smooths the rectangular wave shape switch voltage Vsw appearing at the switch terminal SW to generate the output voltage Vout. The feedback resistors R1 and R2 constitute a feedback voltage generation circuit that generates the feedback voltage Vfb according to the output voltage Vout by voltage division of the output voltage Vout. The feedback voltage Vfb is proportional to the output voltage Vout, and the feedback voltage Vfb also increases and decreases with the increase and decrease of the output voltage Vout.

A modification may be made to use the output voltage Vout itself as the feedback voltage Vfb. In any case, the feedback voltage Vfb is a voltage according to the output voltage Vout. Further, the feedback voltage generation circuit (R1, R2) may be provided inside the power supply control device 100, and in this case, the feedback terminal FB is connected to the output terminal OUT.

Gate signals GH and GL are respectively supplied as drive signals to the gates of the transistors MH and ML, and the transistors MH and ML are turned on and off according to the gate signals GH and GL. The transistor MH is in the on state during the high level period of the gate signal GH, and the transistor MH is in the off state during the low level period of the gate signal GH. Similarly, the transistor ML is in the on state during the high level period of the gate signal GL, and the transistor ML is in the off state during the low level period of the gate signal GL.

Basically, the transistors MH and ML are alternately turned on and off, but there are cases where both the transistors MH and ML are maintained in the off state. That is, the state of the output stage circuit MM becomes any one of an output high state, an output low state, and a both-off state. In the output high state, the transistor MH is in the on state and the transistor ML is in the off state. In the output low state, the transistor MH is in the off state and the transistor ML is in the on state. In the both-off state, both the transistors MH and ML are in the off state. The transistors MH and ML are not simultaneously in the on state. Alternately turning on and off the transistors M1 and M2 in the switching control performed by the switching controller 21 is a concept that includes the intervention of the both-off state considering dead time, etc., between transitions between the output low state and the output high state. In addition, at least one of the transistors MH and ML may be provided outside the power supply control device 100. The entire output stage circuit MM may be provided outside the power supply control device 100.

The switching controller 21 is connected to the feedback terminal FB and receives the feedback voltage Vfb. The switching controller 21 controls the on/off state of each of the transistors MH and ML through level control of the gate signals GH and GL based on the feedback voltage Vfb, thereby generating the desired output voltage Vout at the output terminal OUT. A reference voltage Vref having a predetermined positive DC voltage value is generated within the power supply control device 100, and the switching controller 21 adjusts the output duty of the output stage circuit MM by pulse width modulation so that the feedback voltage Vfb matches the reference voltage Vref. The output duty represents the ratio of the period during which the output stage circuit MM is in the output high state to the sum of the period during which the output stage circuit MM is in the output high state and the period during which the output stage circuit MM is in the output low state.

The switching controller 21 determines the switching frequency of the transistors MH and ML based on the clock signal CLK output from the clock signal generation circuit 10. Specifically, as shown in FIG. 13, the switching controller 21 performs a unit operation that switches the state of the output stage circuit MM from the output low state to the output high state at the timing when a rising edge occurs in the clock signal CLK, and then switches the state of the output stage circuit MM from the output high state to the output low state based on another signal (not shown). This unit operation is repeated in the switching control. The switching controller 21 controls the output duty by generating the above-mentioned another signal so that the error between the feedback voltage Vfb and the reference voltage Vref approaches zero. In addition, the duty of the clock signal CLK is arbitrary.

Since the transistor MH (output transistor) is switched from the off state to the on state each time a rising edge occurs in the clock signal CLK, the switching frequency of the transistor MH matches the frequency f_{CLK}. As described above, the frequency f_{CLK} represents the frequency of the clock signal CLK. However, within the power supply control device 100, a frequency-divided clock signal may be generated by dividing the clock signal CLK by n, and the state of the output stage circuit MM may be switched from the output low state to the output high state at the timing when a rising edge occurs in the frequency-divided clock signal (n represents any integer of 2 or more). In this case, since the transistor MH (output transistor) is switched from the off state to the on state each time a rising edge occurs in the above frequency-divided clock signal, the switching frequency of the transistor MH becomes 1/n times the frequency f_{CLK}. In any case, the transistor MH is switched at a switching frequency proportional to the frequency f_{CLK.}

Although not particularly shown, the power supply control device 100 is provided with an internal power supply circuit that generates an internal power supply voltage based on the input voltage Vin. Each circuit in the power supply control device 100 operates based on the input voltage Vin or the internal power supply voltage. The above-mentioned internal voltage Vreg (see FIG. 5) is a type of internal power supply voltage. Also, while the gate signal GL is a signal referenced to the ground potential, the gate signal GH is a signal referenced to the potential of the switch terminal SW. The gate signal GH at low level has the potential of the switch terminal SW, and the gate signal GH at high level is higher by a predetermined voltage than the potential of the switch terminal SW. The predetermined voltage here is larger than the gate threshold voltage of the transistor MH. A known bootstrap circuit (not shown) can be used to generate a boosted power supply for generating the gate signal GH. The transistor MH may be configured by a P-channel type MOSFET, and in this case, the boosted power supply is unnecessary.

Furthermore, as a modification, a diode rectification system may be adopted in the switching power supply device 1. In this case, as a rectifier element, a synchronous rectification diode having an anode connected to the ground terminal GND and a cathode connected to the switch terminal SW is provided, instead of the transistor ML, in the switching power supply device 1. In this case, only the transistor MH is turned on and off in the switching control of the output stage circuit MM. In any case, the input voltage Vin is converted into the output voltage Vout through the switching of the transistor MH between on and off in the switching control of the output stage circuit MM.

### Third Example

The third example will be described. Although FIG. 12 illustrates an example in which the switching power supply device 1 is a buck type switching power supply device, the switching power supply device 1 may be a boost type or buck-boost type switching power supply device.

The switching power supply device 1 in FIG. 1 may be a composite power supply device that incorporates multiple DC/DC converters. In this case, the first to K-th DC/DC converters included in the multiple DC/DC converters may each be a buck type DC/DC converter that includes the switching controller 21, the output stage circuit MM, the coil L1, the output capacitor C1, and the feedback resistors R1 and R2 shown in FIG. 12 (K is an integer of 2 or more). In this case, the switching controller 21 and the output stage circuit MM in each DC/DC converter are incorporated in the power supply control device 100 (however, each output stage circuit MM may be provided external to the power supply control device 100). In a case where the switching power supply device 1 is a composite power supply device that incorporates multiple DC/DC converters, the power supply control device 100 may be an electronic component classified as a PMIC (Power Management IC).

A single clock signal generation circuit 10 may be shared for the first to K-th DC/DC converters. In this case, within the power supply control device 100, first to K-th clock signals with mutually different phases are generated from the clock signal CLK, and switching control of the output stage circuits MM of the first to K-th DC/DC converters may be performed in synchronization with the first to K-th clock signals, respectively. The frequencies of the first to K-th clock signals are equal to the frequency of the clock signal CLK. Alternatively, first to K-th clock signal generation circuits 10 corresponding to the first to K-th DC/DC converters may be provided in the power supply control device 100.

The multiple DC/DC converters incorporated in the composite power supply device may include a boost type DC/DC converter. The composite power supply device may further include a linear regulator.

The switching power supply device 1 in FIG. 1 may also be an isolated type DC/DC converter having a transformer (not shown). In this case, the switching power supply device 1 includes a primary side circuit and a secondary side circuit mutually isolated from each other, with the primary side winding of the transformer arranged in the primary side circuit and the secondary side winding of the transformer arranged in the secondary side circuit. Then, a voltage higher than the reference potential point of the primary side circuit by the input voltage Vin is applied to the first terminal of the primary side winding, and an output transistor is inserted between the second terminal of the primary side winding and the reference potential point of the primary side circuit. In a case where the switching power supply device 1 is an isolated type DC/DC converter having a transformer, the power conversion circuit 22 (see FIG. 1) is configured by the output transistor, the transformer, and the secondary side circuit, and the switching controller 21 may generate the output voltage Vout in the secondary side circuit by switching the output transistor in synchronization with the clock signal CLK.

### Fourth Example

The fourth example will be described.

The clock signal generation circuit 10 can be applied not only to the switching power supply device 1 but also to any semiconductor device that requires a clock signal. Any semiconductor device that requires a clock signal includes the clock signal generation circuit 10 and a synchronous circuit that operates in synchronization with the clock signal CLK. In the configuration of FIG. 12, the synchronous circuit includes a switching controller 21 and an output stage circuit MM.

For example, a first semiconductor device includes a clock signal generation circuit 10, a half-bridge circuit, and a controller that switches the half-bridge circuit in synchronization with the clock signal CLK, and the synchronous circuit in the first semiconductor device includes the half-bridge circuit and the controller. Any load (for example, an armature winding of a motor) is connected to the half-bridge circuit of the first semiconductor device, and a current is supplied to the load through the half-bridge circuit. In the first semiconductor device, the half-bridge circuit has the same configuration as the output stage circuit MM in FIG. 12, and the controller can switch the half-bridge circuit at the frequency of the clock signal CLK.

Alternatively, for example, a second semiconductor device includes a clock signal generation circuit 10, half-bridge circuits of U-phase, V-phase, and W-phase, and a controller that switches the half-bridge circuits of respective phases in synchronization with the clock signal CLK, and the synchronous circuit in the second semiconductor device includes the half-bridge circuits of respective phases and the controller. A three-phase motor is connected to the half-bridge circuits of U-phase, V-phase, and W-phase in the second semiconductor device, and a current is supplied to the three-phase motor through the half-bridge circuits of respective phases. In the second semiconductor device, the half-bridge circuits of respective phases have the same configuration as the output stage circuit MM in FIG. 12, and the controller can switch the half-bridge circuits of respective phases at the frequency of the clock signal CLK.

The switching power supply device 1 or the above-described semiconductor device can be mounted in any electrical equipment. The electrical equipment may be electrical equipment mounted in a vehicle such as an automobile, a computer device, or a home appliance or industrial equipment.

Without compromising the above-mentioned principles, the relationship between high level and low level for any signal or voltage may be reversed from what has been described above.

The types of channels of the FETs (field-effect transistors) shown in the above embodiments are exemplary. Without compromising the above-mentioned principles, the type of channel of any FET may be changed between P-channel type and N-channel type.

As long as no inconvenience occurs, any transistor mentioned above may be of any type. For example, any transistor described above as a MOSFET may be replaced with a junction type FET, IGBT (Insulated Gate Bipolar Transistor), or bipolar transistor, as long as no inconvenience occurs. Any transistor has a first electrode, a second electrode, and a control electrode. In a FET, one of the first and second electrodes is a drain and the other is a source, and the control electrode is a gate. In an IGBT, one of the first and second electrodes is a collector and the other is an emitter, and the control electrode is a gate. In a bipolar transistor that does not belong to IGBT, one of the first and second electrodes is a collector and the other is an emitter, and the control electrode is a base.

The embodiments of the disclosure may be appropriately modified in various ways within the scope of the technical concept defined in the claims. The above embodiments are merely examples of the embodiments of the disclosure, and the meanings of the terms of the disclosure or components are not limited to those described in the above embodiments. The specific numerical values shown in the above description are merely examples, and can naturally be changed to various numerical values.

### Appendix

The following appendix is provided for the disclosure for which specific configuration examples have been shown in the above embodiments.

A clock signal generation circuit (10) according to one aspect of the disclosure has a configuration (first configuration) including: a first modulation signal generation circuit (11) configured to generate a first modulation signal (Sm1) having a first frequency (f1); a second modulation signal generation circuit (12) configured to generate a second modulation signal (Sm2) having a second frequency (f2) lower than the first frequency; a signal combining circuit (13) configured to generate a composite modulation signal (Smc) by combining the first modulation signal and the second modulation signal; and an oscillator (14) configured to generate a clock signal (CLK) having a frequency according to the composite modulation signal.

This makes it possible to spread the frequency of the clock signal over a wide band. As a result, it is possible to suppress peaks in the power spectrum of radiated noise from the clock signal generation circuit or from a device including the clock signal generation circuit. This leads to characteristic improvement of EMI.

The clock signal generation circuit according to the first configuration above may have a configuration (second configuration) that in the signal combining circuit, the composite modulation signal is generated by combining a first modulation current (Im1) as the first modulation signal and a second modulation current (Im2) as the second modulation signal.

By adopting a system that generates the composite modulation signal through the combination of current signals having different frequencies, it is possible to generate the desired composite modulation signal with a small circuit scale.

The clock signal generation circuit according to the second configuration above may have a configuration (third configuration) that the first modulation signal generation circuit generates the first modulation current (Im1) by converting a modulation voltage (Vm1) having the first frequency into a current signal, the second modulation current includes an addition current (Ia) and a subtraction current (Ib), the signal combining circuit generates a composite current (Imc) by adding the addition current to the first modulation current or subtracting the subtraction current from the first modulation current, and generates a composite voltage (Vmc) as the composite modulation signal by converting the composite current into a voltage signal, and the addition current and the subtraction current vary according to the second frequency.

The clock signal generation circuit according to the third configuration above may have a configuration (fourth configuration) further including a clock controller (15) configured to control operations of the first modulation signal generation circuit, the second modulation signal generation circuit, and the signal combining circuit, in which the clock controller repeatedly sets a unit period (P_{UNIT}) including an addition period in which the addition current is added to the first modulation current and a subtraction period in which the subtraction current is subtracted from the first modulation current, a repetition frequency of a plurality of unit periods is the second frequency, and in each unit period, one of the addition period and the subtraction period is provided after the other of the addition period and the subtraction period.

The clock signal generation circuit according to the fourth configuration above may have a configuration (fifth configuration) that the second modulation signal generation circuit monotonically increases and then monotonically decreases the addition current in the addition period, and monotonically increases and then monotonically decreases the subtraction current in the subtraction period.

The clock signal generation circuit according to any one of the third to fifth configurations above may have a configuration (sixth configuration) that the first modulation signal generation circuit generates the modulation voltage by dividing a predetermined DC voltage (Vreg) using a ladder resistance circuit (111), and provides the modulation voltage with the first frequency by varying a voltage division ratio for generating the modulation voltage from the DC voltage at the first frequency.

A power supply control device according to one aspect of the disclosure is a power supply control device (100) provided in a switching power supply device (1) configured to generate an output voltage (Vout) from an input voltage (Vin) through switching of an output transistor, and may have a configuration (seventh configuration) including the clock signal generation circuit (10) according to any one of the first to sixth configurations; and a switching controller (21) configured to switch the output transistor at a switching frequency according to the clock signal.

A switching power supply device according to one aspect of the disclosure is a switching power supply device (1) configured to generate an output voltage (Vout) from an input voltage (Vin) through switching of an output transistor (MH), and may have a configuration (eighth configuration) including the clock signal generation circuit (10) according to any one of the first to sixth configurations; and a converter (20) including the output transistor and configured to convert the input voltage into the output voltage through switching the output transistor at a switching frequency according to the clock signal.

The switching power supply device according to the eighth configuration above may have a configuration (ninth configuration) that the converter includes: an output stage circuit (MM) including the output transistor (MH) provided between an application terminal of the input voltage and a switch terminal, and a rectifier element (ML) provided between the switch terminal and a ground terminal having a ground potential lower than the input voltage; a rectification smoothing circuit (L1, C1) configured to generate the output voltage by rectifying and smoothing a switch voltage (Vsw) generated at the switch terminal by switching of the output transistor ; and a switching controller (21) configured to perform switching control of the output transistor based on a feedback voltage (Vfb) according to the output voltage.

What is claimed is:

1. A clock signal generation circuit, comprising:
a first modulation signal generation circuit configured to generate a first modulation signal having a first frequency;
a second modulation signal generation circuit configured to generate a second modulation signal having a second frequency lower than the first frequency;
a signal combining circuit configured to generate a composite modulation signal by combining the first modulation signal and the second modulation signal; and
an oscillator configured to generate a clock signal having a frequency according to the composite modulation signal.

2. The clock signal generation circuit according to claim 1, wherein in the signal combining circuit, the composite modulation signal is generated by combining a first modulation current as the first modulation signal and a second modulation current as the second modulation signal.

3. The clock signal generation circuit according to claim 2, wherein the first modulation signal generation circuit generates the first modulation current by converting a modulation voltage having the first frequency into a current signal,
the second modulation current comprises an addition current and a subtraction current,
the signal combining circuit generates a composite current by adding the addition current to the first modulation current or subtracting the subtraction current from the first modulation current, and generates a composite voltage as the composite modulation signal by converting the composite current into a voltage signal, and
the addition current and the subtraction current vary according to the second frequency.

4. The clock signal generation circuit according to claim 3, further comprising a clock controller configured to control operations of the first modulation signal generation circuit, the second modulation signal generation circuit, and the signal combining circuit,
wherein the clock controller repeatedly sets a unit period comprising an addition period in which the addition current is added to the first modulation current and a subtraction period in which the subtraction current is subtracted from the first modulation current,
a repetition frequency of a plurality of unit periods is the second frequency, and
in each unit period, one of the addition period and the subtraction period is provided after the other of the addition period and the subtraction period.

5. The clock signal generation circuit according to claim 4, wherein the second modulation signal generation circuit monotonically increases and then monotonically decreases the addition current in the addition period, and monotonically increases and then monotonically decreases the subtraction current in the subtraction period.

6. The clock signal generation circuit according to claim 3, wherein the first modulation signal generation circuit generates the modulation voltage by dividing a predetermined DC voltage using a ladder resistance circuit, and provides the modulation voltage with the first frequency by varying a voltage division ratio for generating the modulation voltage from the DC voltage at the first frequency.

7. A power supply control device, provided in a switching power supply device configured to generate an output voltage from an input voltage through switching of an output transistor, the power supply control device comprising:
the clock signal generation circuit according to claim 1; and
a switching controller configured to switch the output transistor at a switching frequency according to the clock signal.

8. A switching power supply device configured to generate an output voltage from an input voltage through switching of an output transistor, the switching power supply device comprising:
the clock signal generation circuit according to claim 1; and
a converter comprising the output transistor and configured to convert the input voltage into the output voltage through switching the output transistor at a switching frequency according to the clock signal.

9. The switching power supply device according to claim 8, wherein the converter comprises:
an output stage circuit comprising the output transistor provided between an application terminal of the input voltage and a switch terminal, and a rectifier element provided between the switch terminal and a ground terminal having a ground potential lower than the input voltage;
a rectification smoothing circuit configured to generate the output voltage by rectifying and smoothing a switch voltage generated at the switch terminal by switching of the output transistor; and
a switching controller configured to perform switching control of the output transistor based on a feedback voltage according to the output voltage.
